(19) United States
(12) Patent Application Publication
(10) Pub. No.: US 2024/0429838 A1
(43) Pub. Date: Dec. 26, 2024

(54) ACTUATOR AND ACTUATOR SYSTEM INCLUDING THE SAME

(71) Applicant: ELECTRONICS AND TELECOMMUNICATIONS RESEARCH INSTITUTE, Daejeon (KR)

(72) Inventors: Sung Ryul YUN, Daejeon (KR); Jung-Hwan YOUN, Daejeon (KR); Seung Yeon JANG, Daejeon (KR); Inwook HWANG, Daejeon (KR); Seongcheol MUN, Daejeon (KR); Mi Jeong CHOI, Daejeon (KR)

(21) Appl. No.: 18/744,800

(22) Filed: Jun. 17, 2024

(30) Foreign Application Priority Data
Jun. 20, 2023 (KR) 10-2023-0079241
Jun. 3, 2024 (KR) 10-2024-0072263

(51) Int. Cl. H02N 2/18; H10N 30/857

(52) U.S. Cl. CPC H02N 2/18; H10N 30/857

(57) ABSTRACT

Provided is an actuator system which includes an electroactive polymer film, and a spring surrounded by the electroactive polymer film. At least a portion of the spring is disposed inside the electroactive polymer film.

### CROSS-REFERENCE TO RELATED APPLICATIONS

This U.S. non-provisional patent application claims priority under 35 U.S.C. § 119 of Korean Patent Application No. 10-2023-0079241, filed on Jun. 20, 2023, and Korean Patent Application No. 10-2024-0072263, filed on Jun. 3, 2024, in the Korean Intellectual Property Office, the entire contents of which are hereby incorporated by reference.

### BACKGROUND

### 1. Field of the Invention

The present disclosure herein relates to an actuator and an actuator system including the same, and more particularly, to an actuator including an electroactive polymer film and an actuator system including the same.

### 2. Description of Related Art

Electroactive polymers are materials that move when a voltage is applied and have various advantages such as a fast response speed, large deformation, low power consumption, excellent processability, and characteristics similar to human muscles. Various methods are being studied to develop actuators with excellent operating characteristics and miniaturization using electroactive polymers.

### SUMMARY

The present disclosure provides an actuator having improved operation characteristics and reliability and an actuator system including the same.

An embodiment of the inventive concept provides an actuator system including: an electroactive polymer film; and a spring surrounded by the electroactive polymer film, wherein at least a portion of the spring is disposed inside the electroactive polymer film.

In an embodiment of the inventive concept, an actuator includes: an electroactive polymer film including an upper portion, a lower portion, and a sidewall configured to connect the upper portion to the lower portion; a connection body that is in contact with a bottom surface of the upper portion of the electroactive polymer film; and a spring that is in contact with a bottom surface of the connection body, wherein the spring passes through the lower portion of the electroactive polymer film.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1A is a plan view of an actuator system according to some embodiments;

FIG. 1B is a cross-sectional view taken along line I-I′ of FIG. 1A;

FIG. 2A is an exploded perspective view of the actuator according to some embodiments;

FIG. 2B is a cross-sectional view of the actuator according to some embodiments;

FIG. 3 is a view for explaining a method for driving an actuator system according to some embodiments;

FIG. 4 is an enlarged view of an active actuator of FIG. 3;

FIGS. 5A and 5B are graphs illustrating an amount of change in length of the actuator compared to a frequency of an AC voltage applied to the actuator according to some embodiments;

FIGS. 6A and 6B are graphs illustrating an amount of change in length of the actuator compared to an intensity of the AC voltage applied to the actuator according to some embodiments;

FIG. 7A is a view illustrating a wearable device including the actuator according to some embodiments;

FIG. 7B is a view illustrating a joint including the actuator according to some embodiments; and

FIG. 7C is a view illustrating a gripper including the actuator according to some embodiments.

### DETAILED DESCRIPTION

Hereinafter, an actuator and an actuator system including the same according to embodiments of the inventive concept will be described in detail with reference to the drawings.

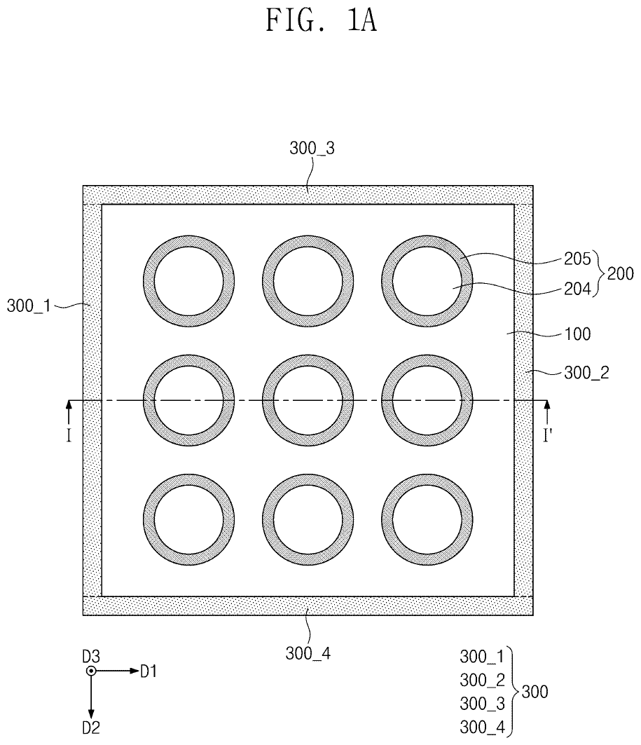

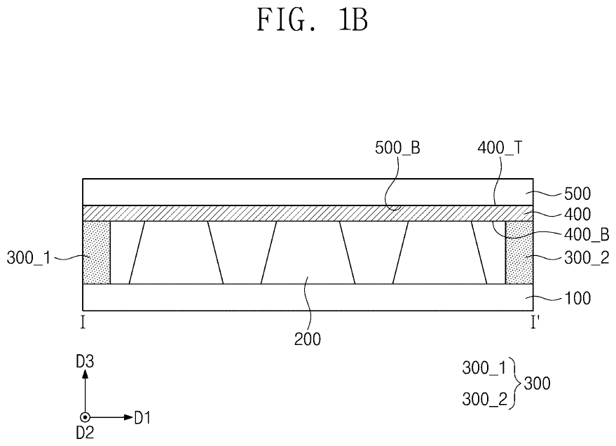

FIG. 1A is a plan view of an actuator system according to some embodiments. FIG. 1B is a cross-sectional view taken along line I-I′ of FIG. 1A.

Referring to FIGS. 1A and 1B, a board 100 may be provided. In some embodiments, the board 100 may be a flexible printed circuit board (flexible PCB). The board 100 may have a shape of a plate extending along a plane extending in a first direction D1 and a second direction D2. The first direction D1 and the second direction D2 may intersect each other. For example, the first direction D1 and the second direction D2 may be horizontal directions orthogonal to each other.

A plurality of actuators 200 may be provided on the board 100. The actuators 200 may be arranged in the first direction D1 and the second direction D2. The actuators 200 may be spaced apart from each other.

A support part 300 may be provided on the board 100. The support part 300 may surround the actuators 200. The support part 300 and the actuators 200 may be spaced apart from each other. The support part 300 may include a first portion 300_1 and a second portion 300_2, which are spaced apart from each other in the first direction D1. The support part 300 may include a third portion 300_3 and a fourth portion 300_4, which are spaced apart from each other in the second direction D2. The first portion 300_1 and the second portion 300_2 may extend in the second direction D2. The third portion 300_3 and the fourth portion 300_4 may extend in the first direction D1.

The first portion 300_1 and the third portion 300_3 of the support part 300 may be connected to each other. The first portion 300_1 and the fourth portion 300_4 of the support part 300 may be connected to each other. The second portion 300_2 and the third portion 300_3 of the support part 300 may be connected to each other. The second portion 300_2 and the fourth portion 300_4 of the support part 300 may be connected to each other.

The actuator 200 may be disposed between the first portion 300_1 and the second portion 300_2 of the support part 300. The actuator 200 may be disposed between the third portion 300_3 and the fourth portion 300_4 of the support part 300.

A thickness of the support part 300 and a thickness of the actuator 200 in the third direction D3 may be the same. In some embodiments, the thickness of the support part 300 in the third direction D3 may be greater than the thickness of the actuator 200 in the third direction D3.

A heating part 400 may be provided on the actuators 200 and the support part 300. The heating part 400 may be in contact with top surfaces of the actuators 200 and a top surface of the support part 300. The support part 300 may be in contact with a bottom surface 400_B of the heating part 400. The top surfaces of the first portion 300_1 and the second portion 300_2 of the support part 300 may be in contact with the bottom surface 400_B of the heating part 400.

In some embodiments, the heating part 400 may have the form of a film. In some embodiments, the heating part 400 may be parallel to the first direction D1 and the second direction D2. In some embodiments, the heating part 400 may include a conductive material.

A stiffness variable polymer film 500 may be provided on the heating part 400. The bottom surface 500_B of the stiffness variable polymer film 500 may be in contact with a top surface 400_T of the heating part 400. The stiffness variable polymer film 500 may include a stiffness variable polymer material.

The heating part 400 may be provided between the stiffness variable polymer film 500 and the actuator 200. The stiffness variable polymer film 500 and the actuator 200 may be spaced apart from each other by the heating part 400. The heating part 400 may be provided between the stiffness variable polymer film 500 and the support part 300. The stiffness variable polymer film 500 and the support part 300 may be spaced apart from each other by the heating part 400.

The actuator system according to some embodiments may include the heating part 400 and the stiffness variable polymer film 500 on the actuator 200, and operations of the stiffness variable polymer film 500 and the actuator 200 may be controlled by the heating part 400.

The actuator system according to some embodiments may include the support part 300 surrounding the actuator 200, and thus, when a shape of the stiffness variable polymer film 500 is changed, a position of the stiffness variable polymer film 500 may be prevented from being misaligned.

In the actuator system according to some embodiments, the stiffness of the support part 300 may be relatively large, and thus, when the actuator 200 operates, the shape of the support part 300 may be constantly maintained, and the operation of the stiffness variable polymer film 500 may be easily controlled.

The actuator system according to some embodiments uses the flexible printed circuit board as the board 100, and thus, even when the shape of the actuator 200 is changed, stability of connection between the actuator 200 and the board 100 may be improved.

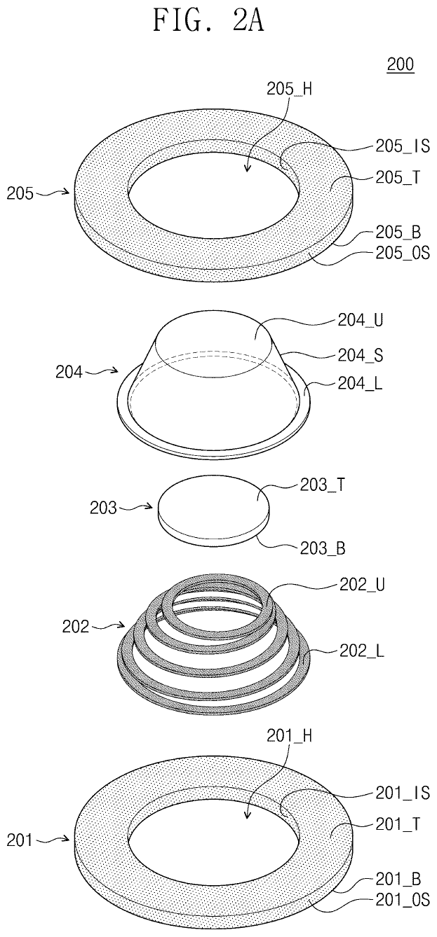

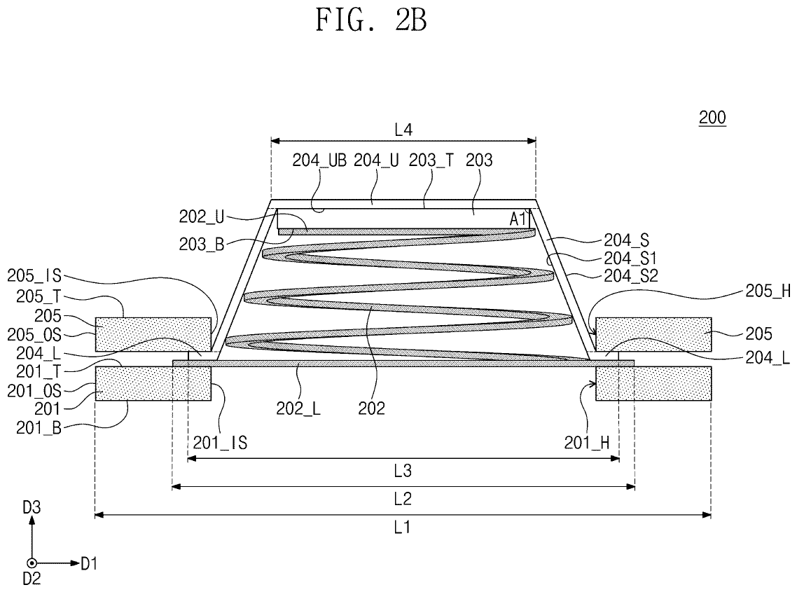

FIG. 2A is an exploded perspective view of the actuator according to some embodiments. FIG. 2B is a cross-sectional view of the actuator according to some embodiments.

Referring to FIGS. 2A and 2B, the actuator 200 may include a lower fixing part 201, a spring 202, a connection body 203, an electroactive polymer film 204, and an upper fixing part 205.

In some embodiments, the lower fixing part 201 may have a ring shape on a plane. An area of each of a top surface 201_T and an area of a bottom surface 201_B of the lower fixing part 201 may be the same. The top surface 201_T and the bottom surface 201_B of the lower fixing part 201 may be flat. The top surface 201_T and the bottom surface 201_B of the lower fixing part 201 may be parallel to each other. The top surface 201_T of the lower fixing part 201 may be parallel to the first direction D1 and the second direction D2. The bottom surface 201_B of the lower fixing part 201 may be parallel to the first direction D1 and the second direction D2.

The lower fixing part 201 may include an outer wall 201_OS and an inner wall 201_IS. A lower hole 201_H may be defined inside the lower fixing part 201 by the inner wall 201_IS of the lower fixing part 201. The lower hole 201_H may have a circular shape on the plane. A diameter of the lower hole 201_H may be less than a diameter of the outer wall 201_OS of the lower fixing part 201. A width L1 of the lower fixing part 201 in the first direction D1 may be greater than a thickness of the lower fixing part 201 in the third direction D3.

The outer wall 201_OS of the lower fixing part 201 may connect the top surface 201_T to the bottom surface 201_B. The inner wall 201_IS of the lower fixing part 201 may connect the top surface 201_T to the bottom surface 201_B. A surface area of the outer wall 201_OS of the lower fixing part 201 may be greater than a surface area of the inner wall 201_IS.

A spring 202 may be provided on the lower fixing part 201. The spring 202 may be in contact with a top surface 201_T of the lower fixing part 201. A diameter of the spring 202 may gradually increase as it approaches the lower fixing part 201.

The spring 202 may include the uppermost portion 202_U and the lowermost portion 202_L. In some embodiments, each of the uppermost portion 202_U and the lowermost portion 202_L of the spring 202 may have a ring shape on the plane. A width of the lowermost portion 202_L of the spring 202 in the first direction D1 may be greater than a width of the uppermost portion 202_U of the spring 202 in the first direction D1.

The lowermost portion 202_L of the spring 202 may be in contact with the top surface 201_T of the lower fixing part 201. A width L2 of the lowermost portion 202_L of the spring 202 in the first direction D1 may be less than a width L1 of the lower fixing part 201 in the first direction D1. Stiffness of the spring 202 may be less than that of the support part 300 (see FIG. 1B).

In some embodiments, the spring 202 may include stainless steel. For example, the spring may include SUS304. In some embodiments, a spring constant of the spring 202 may be about 0.04 N/m or more and about 0.16 N/m or less. In some embodiments, the spring constant of the spring 202 may be about 0.16 N/m or more.

The connection body 203 may be provided on the spring 202. A bottom surface 203_B of the connection body 203 may be in contact with the spring 202. The connection body 203 may be in contact with the uppermost portion 202_U of the spring 202. In some embodiments, each of a top surface 203_T and a bottom surface 203_B of the connection body 203 may have a circular shape. An area of the top surface 203_T and an area of the bottom surface 203_B of the connection body 203 may be the same. A width of the connection body 203 in the first direction D1 may be greater than a thickness of the connection body 203 in the third direction D3.

The width of the connection body 203 in the first direction D1 may be less than the width L2 of the lowermost portion 202_L of the spring 202 in the first direction D1. The width of the connection body 203 in the second direction D2 may be less than the width of the lowermost portion 202_L of the spring 202 in the second direction D2. In some embodiments, the width of the connection body 203 in the first direction D1 may be equal to the width of the uppermost portion 202_U of the spring 202 in the first direction D1.

A diameter of the spring 202 may gradually increase in a direction that is away from the connection body 203. The width of the spring 202 in the first direction D1 may gradually increase in a direction that is away from the connection body 203. Stiffness of the connection body 203 may be greater than that of the spring 202.

An electroactive polymer film 204 may be provided on the connection body 203. The electroactive polymer film 204 may include a lower portion 204_L, an upper portion 204_U, and a sidewall 204_S. The sidewall 204_S of the electroactive polymer film 204 may connect the upper portion 204_U to the lower portion 204_L.

The electroactive polymer film 204 may cover the spring 202. The lower portion 204_L of the electroactive polymer film 204 may be in contact with the lowermost portion 202_L of the spring 202. The sidewall 204_S and the lower portion 204_L of the electroactive polymer film 204 may surround the spring 202.

The spring 202 may pass through the lower portion 204_L of the electroactive polymer film 204. At least a portion of the spring 202 may be disposed within the electroactive polymer film 204. For example, the uppermost portion 202_U of the spring 202 may be disposed within the electroactive polymer film 204.

The sidewall 204_S of the electroactive polymer film 204 may include a first surface 204_S1 and a second surface 204_S2. In some embodiments, the first surface 204_S1 may be in contact with the spring 202. The first surface 204_S1 may be connected to a bottom surface of the lower portion 204_L and a bottom surface 204_UB of the upper portion 204_U of the electroactive polymer film 204. The second surface 204_S2 may be connected to the top surface of the lower portion 204_L and the top surface 204_U of the electroactive polymer film 204.

The bottom surface 204_UB of the upper portion 204_U of the electroactive polymer film 204 may be in contact with the top surface 203_T of the connection body 203. An area of the bottom surface 204_UB of the upper portion 204_U of the electroactive polymer film 204 may be equal to an area of the top surface 203_T of the connection body 203.

A width L3 of the lower portion 204_L of the electroactive polymer film 204 in the first direction D1 is greater than a width L4 of the upper portion 204_U of the electroactive polymer film 204 in the first direction D1. A width of the lower portion 204_L of the electroactive polymer film 204 in the second direction D2 may be greater than a width of the upper portion 204_U of the electroactive polymer film 204 in the second direction D2.

The top surface and the bottom surface 204_UB of the upper portion 204_U of the electroactive polymer film 204 may be parallel to the first direction D1 and the second direction D2. The top surface and the bottom surface of the lower portion 204_L of the electroactive polymer film 204 may be parallel to the first direction D1 and the second direction D2. The upper portion 204_U of the electroactive polymer film 204 may have a circular shape on the plane. The lower portion 204_L of the electroactive polymer film 204 may have a ring shape on the plane. A diameter of the lower portion 204_L of the electroactive polymer film 204 may be greater than a diameter of the upper portion 204_U.

The sidewall 204_S of the electroactive polymer film 204 may be inclined with respect to the upper portion 204_U and the lower portion 204_L. An angle A1 between the first surface 204_S1 of the electroactive polymer film 204 and the bottom surface 204_UB of the upper portion 204_U of the electroactive polymer film 204 may be greater than about 90 degrees and less than about 180 degrees.

An upper fixing part 205 may be provided on the electroactive polymer film 204. In some embodiments, the upper fixing part 205 may have a ring shape on the plane. An area of the top surface 205_T and an area of the bottom surface 205_B of the upper fixing part 205 may be the same. Each of the top surface 205_T and the bottom surface 205_B of the upper fixing part 205 may be flat. The top surface 205_T and the bottom surface 205_B of the upper fixing part 205 may be parallel to each other. The top surface 205_T of the upper fixing part 205 may be parallel to the first direction D1 and the second direction D2. The bottom surface 205_B of the upper fixing part 205 may be parallel to the first direction D1 and the second direction D2.

The upper fixing part 205 may be in contact with the top surface of the lower portion 204_L of the electroactive polymer film 204. In some embodiments, the upper fixing part 205 may be in contact with the second surface 204_S2 of the electroactive polymer film 204. The electroactive polymer film 204 may pass through the upper fixing part 205.

The upper fixing part 205 may include an outer wall 205_OS and an inner wall 205_IS. An upper hole 205_H may be defined inside the upper fixing part 205 by the inner wall 205_IS of the upper fixing part 205. The upper hole 205_H may have a circular shape on the plane. A diameter of the upper hole 205_H may be less than a diameter of the outer wall 205_OS of the upper fixing part 205. The electroactive polymer film 204 may pass through the upper hole 205_H.

A width of the upper fixing part 205 in the first direction D1 may be equal to a width of the lower fixing part 201 in the first direction D1. In some embodiments, the width of the upper fixing part 205 in the first direction D1 may be greater than the thickness of the upper fixing part 205 in the third direction D3.

The outer wall 205_OS of the upper fixing part 205 may connect the top surface 205_T to the bottom surface 205_B. The inner wall 205_IS of the upper fixing part 205 may connect the top surface 205_T to the bottom surface 205_B. A surface area of the outer wall 205_OS of the upper fixing part 205 may be greater than a surface area of the inner wall 205_IS.

The actuator 200 according to some embodiments includes a spring 202, and the electroactive polymer film 204 may cover the spring 202. Thus, an operation direction of the electroactive polymer film 204 may be controlled by the spring 202. In addition, when the actuator 200 is miniaturized, it is possible to prevent an amount of change in shape of the electroactive polymer film 204 from being reduced.

The actuator 200 according to some embodiments may include the spring 202 to apply tension to the electroactive polymer film 204. The tension may be applied to the electroactive polymer film 204, and thus, the electroactive polymer film 204 may become thinner. As the electroactive polymer film 204 becomes thinner, a phenomenon of irreversible deformation of the electroactive polymer film 204 may be reduced.

The actuator 200 according to some embodiments may include the lower fixing part 201 and the upper fixing part 205, which are in contact with the spring 202 and the electroactive polymer film 204 to prevent the spring 202 and the electroactive polymer film 204 from moving.

The actuator 200 according to some embodiments may include the connection body 203 to constantly maintain the shape of the top surface of the electroactive polymer film 204. In addition, the spring 202 and the electroactive polymer film 204 may be easily connected, and when the shape of the electroactive polymer film 204 is changed, the connection between the spring 202 and the electroactive polymer film 204 may be stable.

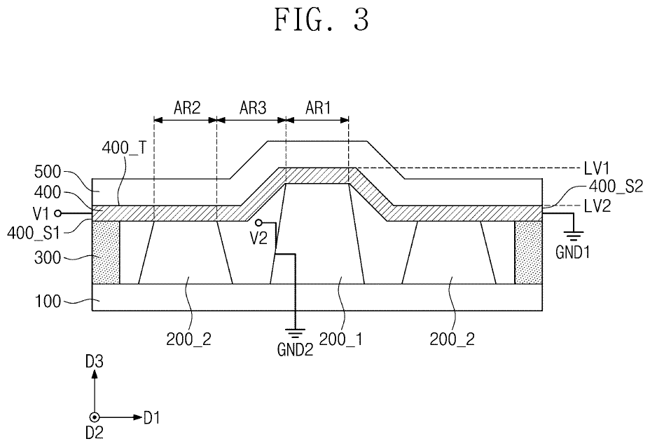

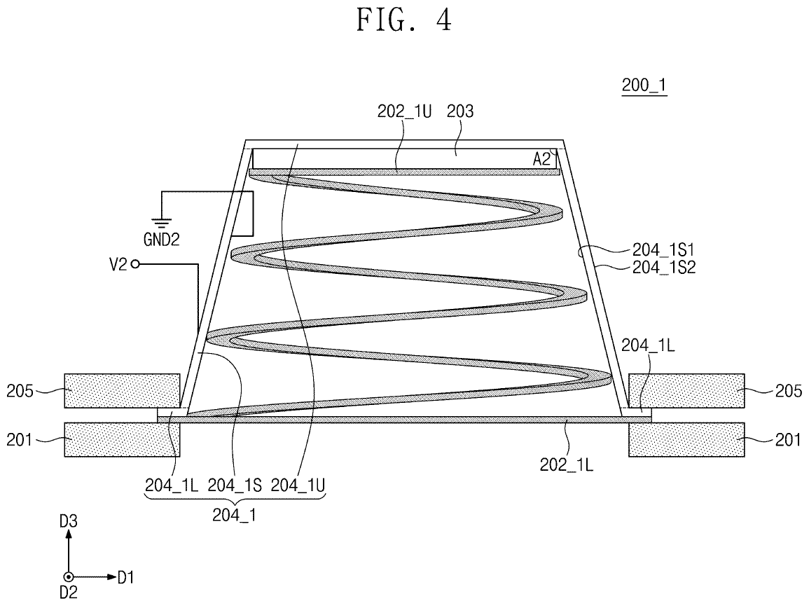

FIG. 3 is a view for explaining a method for driving an actuator system according to some embodiments. FIG. 4 is an enlarged view of the active actuator of FIG. 3.

Referring to FIGS. 3 and 4, a method for driving an actuator system may include heating a heating part 400. In some embodiments, the heating of the heating part 400 may include heating the heating part 400 using Joule heating. The heating of the heating part 400 using Joule heating may include applying a first voltage V1 to a first surface 400_S1 of the heating part 400 and applying a first ground voltage GND1 to a second surface 400_S2 of the heating part 400. Current may flow in the heating part 400 due to the voltage applied to the heating part 400.

As the heating part 400 is heated, a stiffness variable polymer film 500 may be heated. In some embodiments, the stiffness variable polymer film 500 may be heated by heat conduction. The heat of the heating part 400 may move to the stiffness variable polymer film 500, and the stiffness variable polymer film 500 may be heated. As the stiffness variable polymer film 500 is heated, the stiffness of the stiffness variable polymer film 500 may decrease.

The method of driving the actuator system may further include applying a voltage to at least one actuator 200. In some embodiments, the applying of the voltage to the actuator 200 and the heating of the stiffness variable polymer film 500 may be performed simultaneously. In some embodiments, a second ground voltage GND2 and a second voltage V2 may be applied to the first surface 204_S1 (see FIG. 2B) and the second surface 204_S2 of the actuator 200, respectively. In some embodiments, the first ground voltage GND1 and the second ground voltage GND2 may have the same potential.

In some embodiments, the second voltage V2 may be a direct current voltage. In some embodiments, the second voltage V2 may be an alternating current voltage. In some embodiments, the second voltage V2 may be an alternating current voltage including an offset voltage.

In the state in which the heating part 400 and the stiffness variable polymer film 500 are heated, the voltage may be applied to the actuator 200, and thus, a length of the actuator 200 in the third direction D3 may be changed. The actuator 200 of which the length in the third direction D3 is changed due to the applying of the voltage may be defined as an active actuator 200_1. The actuator 200 of which the length in the third direction D3 is not changed because no voltage is applied may be defined as an inactive actuator 200_2. A length of the active actuator 200_1 in the third direction D3 may be greater than a length of the inactive actuator 200_2 in the third direction D3.

The changing of the length of the actuator 200 in the third direction D3 may include changing a shape of the electroactive polymer film 204. The electroactive polymer film 204 of which the shape has changed may be defined as an active film 204_1. The active film 204_1 may be the electroactive polymer film 204 of the active actuator 200_1. The electroactive polymer film 204 of which the shape is not changed may be defined as an inactive film. The inactive film may be the electroactive polymer film 204 of the inactive actuator 200_2. A level of an upper portion 204_1U of the active film 204_1 may be greater than a level of an upper portion of the inactive film 204_1.

The changing of the length of the actuator 200 in the third direction D3 may include changing a shape of the spring 202. The spring 202 of which the shape has changed may be defined as an active spring 202_1. The active spring 202_1 may be the spring of the active actuator 200_1. The spring 202 of which the shape is not changed may be defined as an inactive spring. The inactive spring may be the spring of the inactive actuator 200_2.

A length of the active spring 202_1 in the third direction D3 may be greater than a length of the inactive spring in the third direction D3. A width of the uppermost portion 202_1U of the active spring 202_1 in the first direction D1 may be equal to the width of the uppermost portion of the inactive spring 202_1 in the first direction D1. A width of the lowermost portion 202_1L of the active spring 202_1 in the first direction D1 may be equal to a width of the lowermost portion of the inactive spring 202_1 in the first direction D1.

As the length of the actuator 200 in the third direction D3 is changed, the shapes of the heating part 400 and the stiffness variable polymer film 500 may be changed. The top surface 400_T of the heating part 400 may include a first portion AR1 overlapping the active actuator 200_1 in the third direction D3, and a second portion AR2 overlapping the inactive actuator 200_2 in the third direction D3, and a third portion AR3 connecting the first portion AR1 to the second portion AR2.

The first portion AR1 and the second portion AR2 of the top surface 400_T of the heating part 400 may be parallel to the first direction D1 and the second direction D2. At least a portion of the third portion AR3 of the top surface 400_T of the heating part 400 may be inclined toward the first and second portions AR1 and AR2 of the top surface 400_T of the heating part 400. The third portion of the top surface 400_T of the heating part 400 may intersect each other with respect to the first direction D1 and the second direction D2. A level LV1 of the first portion AR1 of the top surface 400_T of the heating part 400 may be greater than a level LV2 of the second portion AR2 of the top surface 400_T of the heating part 400.

The method for driving the actuator system may further include cooling the heating part 400 and the stiffness variable polymer film 500. The stiffness variable polymer film 500 may be cooled to increase in stiffness of the stiffness variable polymer film 500.

The method for driving the actuator system according to some embodiments may include heating the stiffness variable polymer film 500 using the heating part 400 and cooling the stiffness variable polymer film 500, and thus, after the cooling, even if the voltage applied to the actuator 200 is removed, the shape of the stiffness variable polymer film 500 may be maintained.

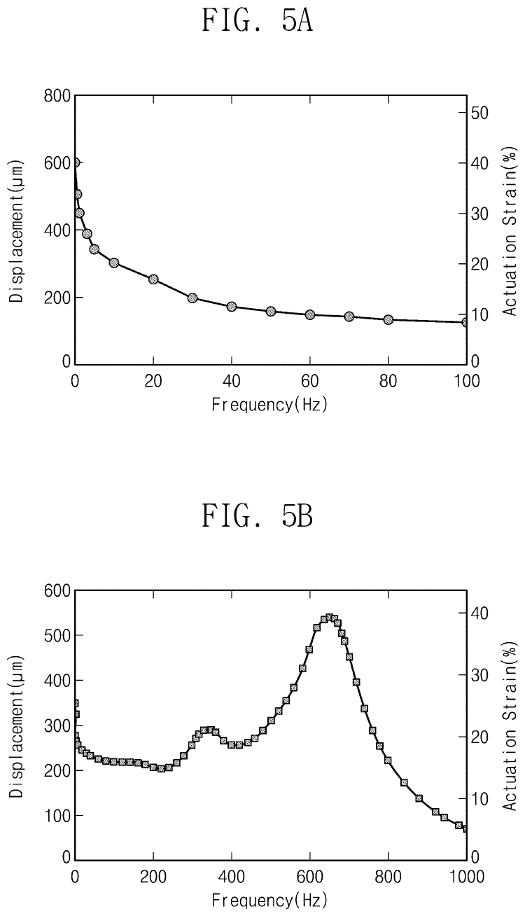

FIGS. 5A and 5B are graphs illustrating an amount of change in length of the actuator compared to a frequency of the AC voltage applied to the actuator according to some embodiments. An x-axis represents a frequency of the alternating voltage applied to the actuator, and a y-axis represents an amount of change and a rate of change in length of the actuator.

Referring to FIGS. 3, 4, 5A, and 5B, the actuator 200 may include the spring 202, and the decrease in amount of change in length of the actuator 200 due to the increase in frequency of the alternating voltage applied to the actuator 200 may be relatively small. When the frequency of the alternating voltage applied to the actuator 200 is about 20 Hz or more and about 100 Hz or less, the decrease in amount of change in length of the actuator 200 may be relatively small.

The amount of change in length of the actuator 200 as the frequency of the alternating voltage applied to the actuator 200 increases below a resonance frequency of the actuator 200 may be less than the amount of change in length of the actuator 200 due to the increase in frequency of the alternating voltage above the resonance frequency.

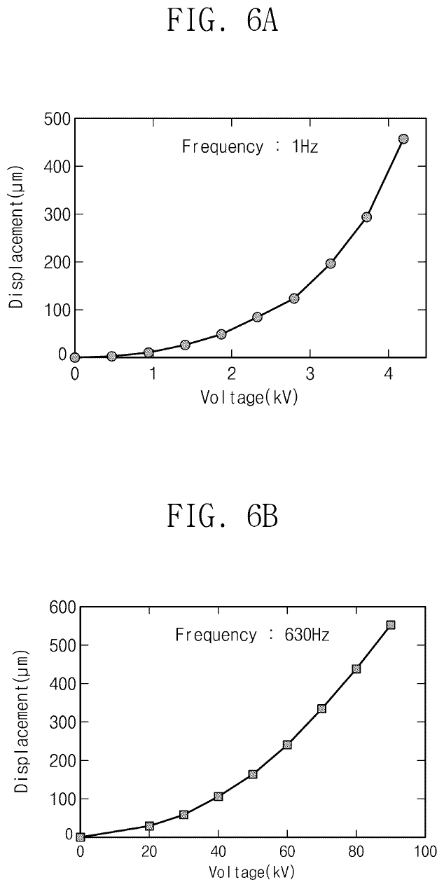

FIGS. 6A and 6B are graphs illustrating an amount of change in length of the actuator compared to an intensity of the AC voltage applied to the actuator according to some embodiments. An x-axis represents an intensity of the alternating voltage applied to the actuator, and a y-axis represents an amount of change in shape of the actuator.

Referring to FIGS. 3, 4, 6a, and 6b, as the intensity of the alternating current voltage applied to the actuator 200 increases, the amount of change in shape of the actuator 200 may increase.

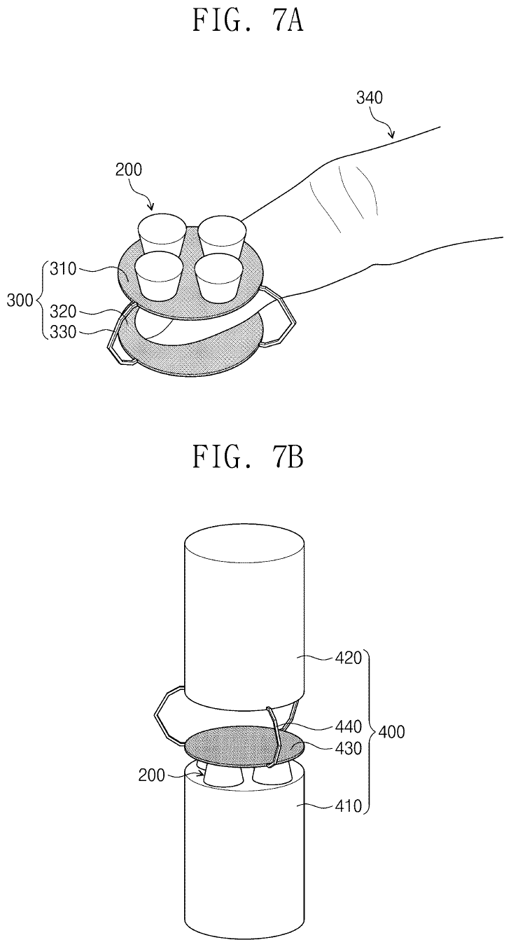

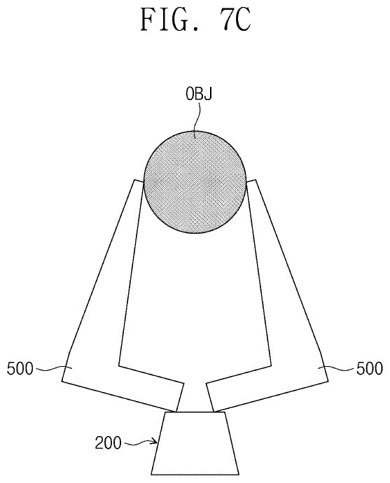

FIG. 7A is a view illustrating a wearable device including the actuator according to some embodiments.

Referring to FIG. 7A, the actuator 200 may be mounted on a wearable device 300. The wearable device 300 may include an upper plate 310, a lower plate 320, and device connection bodies 330. A portion 340 of the human body may be inserted between the upper plate 310 and the lower plate 320. The portion 340 of the human body may be, for example, a finger.

In some embodiments, the wearable device 300 may be a haptic device worn on a finger. Vibration and a pressure may be generated in the wearable device 300 by the actuator 200. The wearer may sense the vibration and the pressure of the wearable device 300 through the portion 340 of the human body and receive information about tactile sensation and magnitude and direction of force generated from the actuator 300.

FIG. 7B is a view illustrating a joint including the actuator according to some embodiments.

Referring to FIG. 7B, the actuator 200 may be mounted on a joint 400. The joint 400 may include a first operation part 410, a second operation part 420, an operation auxiliary plate 430, and joint connection parts 440.

In some embodiments, joint 400 may be a multiple degrees of freedom joint. The first operation part 410 and the second operation part 420 of the joint 400 may move by the actuator 200.

FIG. 7C is a view illustrating a gripper including the actuator according to some embodiments.

Referring to FIG. 7C, the actuator 200 may be mounted on a gripper 500. The gripper 500 may move by the actuator 200. The actuator 200 may move the gripper 500 to grab an object (OBJ).

The actuator and the actuator system including the same according to the embodiments of the inventive concept may include the spring surrounded by the electroactive polymer film so that the actuator is deformed in the specific direction and is easily manufactured in a miniaturized structure.

The actuator and the actuator system including the same according to the embodiments of the inventive concept may include the spring surrounded by the electroactive polymer film, and thus, when the alternating voltage is applied to the actuator, the phenomenon of the deformation attenuation may be reduced.

Although the embodiment of the inventive concept is described with reference to the accompanying drawings, those with ordinary skill in the technical field of the inventive concept pertains will be understood that the present disclosure can be carried out in other specific forms without changing the technical idea or essential features. Therefore, the above-disclosed embodiments are to be considered illustrative and not restrictive.

What is claimed is:

1. An actuator system comprising:
an electroactive polymer film; and
a spring surrounded by the electroactive polymer film,
wherein at least a portion of the spring is disposed inside the electroactive polymer film.

2. The actuator of claim 1, further comprising a connection body between the spring and the electroactive polymer film,
wherein stiffness of the connection body is greater than that of the spring.

3. The actuator of claim 2, wherein a diameter of the spring gradually increases in a direction that is away from the connection body.

4. The actuator of claim 2, wherein a top surface of the connection body has a circular shape.

5. The actuator of claim 1, wherein the electroactive polymer film comprises:
an upper portion;
a lower portion; and
a sidewall configured to connect the upper portion to the lower portion,
wherein a width of the lower portion of the electroactive polymer film is greater than that of the upper portion of the electroactive polymer film.

6. The actuator of claim 5, wherein the spring passes through the lower portion of the electroactive polymer film, and
the spring is surrounded by the lower portion and the sidewall of the electroactive polymer film.

7. The actuator of claim 5, further comprising a connection body that is in contact with a bottom surface of the upper portion of the electroactive polymer film,
wherein the spring is in contact with a bottom surface of the connection body.

8. The actuator of claim 5, further comprising a lower fixing part that is in contact with the lowermost portion of the spring.

9. The actuator of claim 8, further comprising an upper fixing part that is in contact with a top surface of the lower portion of the electroactive polymer film.

10. The actuator of claim 1, further comprising:
a heating part on the electroactive polymer film; and
a stiffness variable polymer film on the heating part.

11. The actuator of claim 10, wherein the stiffness variable polymer film and the electroactive polymer film are spaced apart from each other by the heating part,
the stiffness variable polymer film is in contact with a top surface of the heating part, and
the electroactive polymer film is in contact with a bottom surface of the heating part.

12. The actuator of claim 11, further comprising:
a board; and
a support part on the board,
wherein the support part is in contact with the bottom surface of the heating part, and
the support part is configured to surround the electroactive polymer film.

13. The actuator of claim 12, wherein the support part comprises a first portion and a second portion, which are spaced apart from each other,
the electroactive polymer film is disposed between the first portion and the second portion of the support part, and
the bottom surface of the heating part is in contact with a top surface of the first portion of the support part and a top surface of the second portion of the support part.

14. The actuator of claim 12, wherein the board comprises a flexible PCB.

15. The actuator of claim 12, wherein stiffness of the support part is greater than that of the spring.

16. An actuator comprising:
an electroactive polymer film comprising an upper portion, a lower portion, and a sidewall configured to connect the upper portion to the lower portion;
a connection body that is in contact with a bottom surface of the upper portion of the electroactive polymer film; and
a spring that is in contact with a bottom surface of the connection body,
wherein the spring passes through the lower portion of the electroactive polymer film.

17. The actuator of claim 16, wherein the spring is in contact with the sidewall of the electroactive polymer film.
